(19) United States
(12) Patent Application Publication
(10) Pub. No.: US 2024/0355643 A1
(43) Pub. Date: Oct. 24, 2024

(54) SEMICONDUCTOR DEVICE WITH A PARTIAL SHIELDING LAYER AND A METHOD FOR MAKING THE SAME

(71) Applicant: JCET STATS ChipPAC Korea Limited, Incheon (KR)

(72) Inventors: Bom LEE, Incheon (KR); SeongHwan PARK, Incheon (KR); InHo SEO, Seoul (KR); SeungHyun LEE, Incheon (KR)

(21) Appl. No.: 18/639,994

(22) Filed: Apr. 19, 2024

(30) Foreign Application Priority Data
Apr. 20, 2023 (CN) 202310427315.3

(51) Int. Cl. H01L 21/56; H01L 23/552

(52) U.S. Cl. CPC H01L 21/561; H01L 23/552

(57) ABSTRACT

A method for making a semiconductor device is provided. The method comprises: providing a package substrate strip mounted thereon multiple sets of first electronic components and multiple sets of second electronic components; forming an encapsulant layer on the package substrate strip that covers the multiple sets of first electronic components; forming a first shielding material by spray coating such that the first shielding material extends continuously from a top surface of the encapsulant layer to a top surface of the package substrate strip to cover at least a side surface of the encapsulant layer facing towards the multiple sets of second electronic components; singulating the package substrate strip into individual semiconductor packages with respective package substrates; and forming a second shielding material on the encapsulant layer by sputtering, wherein the second shielding material at least partially overlaps with the first shielding material.

### TECHNICAL FIELD

The present application generally relates to semiconductor technology, and more particularly, to a semiconductor device with a partial shielding layer, and a method for making a semiconductor device with a partial shielding layer.

### BACKGROUND OF THE INVENTION

For electronic components in an electronic device, electromagnetic interference (EMI) shielding needs to be implemented to prevent disruption by electromagnetic field, electrostatic field, etc. As semiconductor package design becomes more complex and compact, selective EMI shielding technology with high accuracy is required. Among various methods of EMI shielding, a cap-based sputtering method or a spray coating method may be used to form a partial shield on the semiconductor package.

As shown in FIG. 1A, in a semiconductor device 10 in the form of a system-in-package (SiP) module, an encapsulant layer 12 is usually molded on a substrate 14 to protect electronic components 11, which are further shielded by a shielding layer (not shown). Other unshielded electronic components 18, for example border-to-border connectors are mounted on the same substrate 14.

Conventionally, a package strip 20 is first singulated into individual pieces and then electronic components are sealed within the encapsulant layer 22 to form a semiconductor package. After that, as shown in FIGS. 1B and 1C, a spray coating method can be applied to the semiconductor package to form a partial shielding layer 26 from a top surface of the encapsulant layer 22 to a top surface of the substrate 24 close to unshielded electronic components 28. However, as can be seen in FIG. 1D, the shielding material of the shielding layer 26 may flow down to a sidewall of the encapsulant layer 22, which may induce non-uniformity of the shielding layer 26 on the encapsulant layer 22.

In case of forming the partial shielding layer 26 using a cap-based sputtering method as illustrated in FIG. 1E, in order to satisfy the minimum sputtering thickness with the shielding effect, a minimum clearance or gap e between the encapsulant layer 22 and a cap 29 covering the unshielded electronic components 28 is required to avoid thin sputtering thickness due to close cap position, thus resulting in package design constraints.

Therefore, a need exists for an improved method for making semiconductor devices with partial shielding layers.

### SUMMARY OF THE INVENTION

An objective of the present application is to provide a semiconductor device with a partial shielding layer and a method for making such semiconductor device.

According to an aspect of the present application, a method for making a semiconductor device is provided. The method comprises: providing a package substrate strip mounted thereon multiple sets of first electronic components and multiple sets of second electronic components; forming an encapsulant layer on the package substrate strip that covers the multiple sets of first electronic components; forming a first shielding material by spray coating such that the first shielding material extends continuously from a top surface of the encapsulant layer to a top surface of the package substrate strip to cover at least a side surface of the encapsulant layer facing towards the multiple sets of second electronic components; singulating the package substrate strip into individual semiconductor packages with respective package substrates; and forming a second shielding material on the encapsulant layer by sputtering, wherein the second shielding material at least partially overlaps with the first shielding material.

According to another aspect of the present application, a method for making a semiconductor device is provided. The method comprises: providing a package substrate mounted thereon first electronic components and second electronic components; forming an encapsulant layer on the package substrate that covers the first electronic components; forming a first shielding material by spray coating such that the first shielding material extends continuously from a top surface of the encapsulant layer to a top surface of the package substrate strip to cover at least a side surface of the encapsulant layer facing towards the second electronic components; and forming a second shielding material on the encapsulant layer by sputtering, wherein the second shielding material at least partially overlaps with the first shielding material.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIGS. 1A to 1E illustrate selective EMI shielding technologies for semiconductor devices.

FIGS. 2A to 2G illustrate various steps of a method for making a semiconductor device, or particularly, forming a partial shielding layer on a semiconductor package strip, according to an embodiment of the present application.

FIGS. 3A and 3B illustrate alternative steps of forming a second shielding material according to two embodiments of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

As aforementioned, both the spray coating process and the cap-based sputtering process may have some drawbacks in forming a partial shielding layer on an encapsulant layer of a semiconductor device. In order to address these problems, the inventors of the present application conceived a new process that utilizes both the spray coating process and the cap-based sputtering process to form a partial shielding layer on an encapsulant layer of a semiconductor device. The shielding layer formed on the semiconductor device using the spray coating process can supplement or compensate for thin sputtering thickness at a sidewall of the encapsulant layer using the cap-based sputtering process, and thus it is not desired to increase a gap between the encapsulant layer and unshielded components outside of the encapsulant layer.

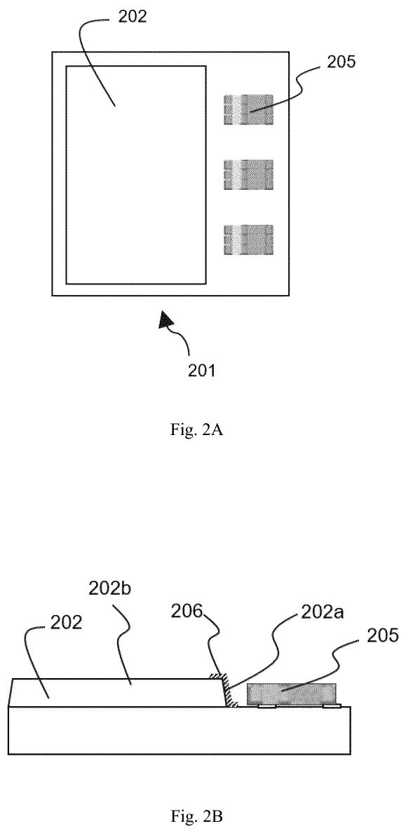

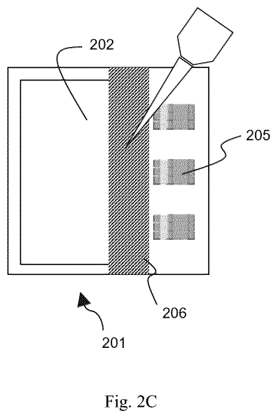

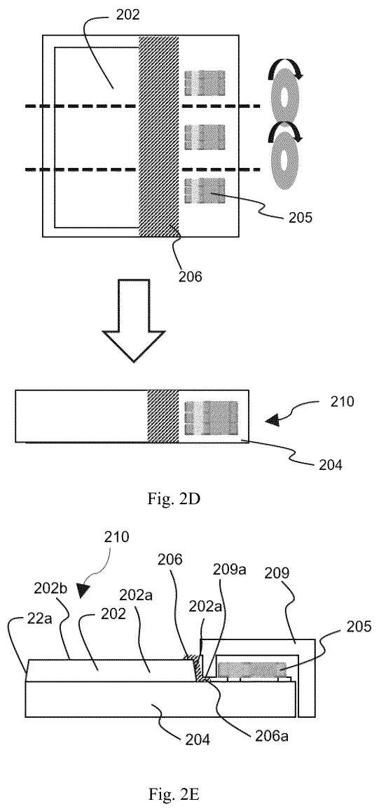

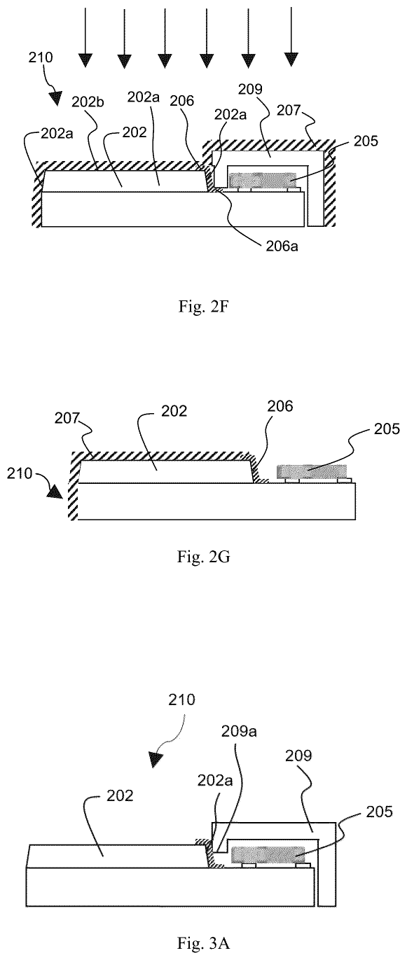

FIGS. 2A to 2G illustrate various steps of a method for making a semiconductor device, or particularly, forming a partial shielding layer on a semiconductor package strip, according to an embodiment of the present application.

As shown in FIG. 2A, a package substrate strip 201 is provided, which may be later singulated into multiple pieces each corresponding to a semiconductor package. The package substrate strip 201 may include multiple sets of first electronic components (not shown) mounted thereon, while each set of first electronic components correspond to a semiconductor package to be separated from the package substrate strip 201. The package substrate strip 201 may include at least an insulating layer and a conductive layer having conductive patterns and one or more interconnection structures formed in the package substrate strip 201. For example, the package substrate strip 201 may include one or more laminated layers of polytetrafluoroethylene pre-impregnated, FR-4, FR-1, CEM-1, or CEM-3 with a combination of phenolic cotton paper, epoxy, resin, woven glass, matte glass, polyester, and other reinforcement fibers or fabrics. The package substrate strip 201 can also be a multi-layer flexible laminate, ceramic, copper clad laminate, or glass. The one or more interconnection structures may include contact pads, conductive traces, and conductive vias configured as necessary to implement a desired signal routing. The first electronic components may include a digital signal processor (DSP), a microcontroller, a microprocessor, a network processor, a power management processor, an audio processor, a video processor, an RF circuit, a wireless baseband system-on-chip (SoC) processor, a sensor, a memory controller, a memory device, an application specific integrated circuit, etc. The first electronic components may also include discrete components such as resistors, capacitors, inductors, etc.

An encapsulant layer 202 is formed on the package substrate strip 201 by molding to cover the first electronic components and a portion of a top surface of the package substrate strip 201 surrounding the first electronic components. The encapsulant layer 202 may be deposited on the package substrate strip 201 using compressive molding, transfer molding or liquid encapsulant molding. In some embodiments, the encapsulant layer 202 may be made of a polymer composite material such as epoxy resin with filler, epoxy acrylate with filler, or polymer with proper filler, for example. The encapsulant layer 202 is preferably non-conductive. The encapsulant layer 202 may also provide structural support and/or protect the first electronic components from external elements or contaminants. The encapsulant layer 202 may be deposited with at least one shielding layer, as will be elaborated in more details below. In some embodiments, a grinding operation can be performed on the encapsulant layer 202 to reduce a thickness of the encapsulant layer 202.

In some embodiments, the encapsulant layer 202 may be formed using an injection molding process where a mold chase (not shown) is used. During the injection molding process, the mold chase may cover the first electronic components and accommodate them within a mold cavity. To allow for easy removal of the mold chase after the injection molding process, the mold cavity may have a truncated shape such as a truncated prism. As such, the encapsulant layer 202 may be formed with a shape of a truncated prism, with sloping sidewalls at its periphery. However, in some other embodiments, the encapsulant layer 202 may alternatively have generally vertical sidewalls.

In addition to the first electronic components covered by the encapsulant layer 202, the package substrate strip 201 may include one or more second electronic components 205 separated from and uncovered by the encapsulant layer 202. These second electronic components 205 may have a different requirement on EMI shielding, for example due to their respective functions in the semiconductor devices to be formed. In some embodiments, the uncovered electronic components 205 may include board-to-board connectors, antennas or other components that do not require EMI shielding. The second electronic components 205 may be disposed away from the encapsulant layer 202 at a predetermined distance, depending on an extension of a shielding layer to be formed along the top surface of the package substrate strip 201, which will be elaborated below.

As illustrated in FIG. 2B which shows a cross sectional view of the package substrate strip, a first shielding material 206 may then be deposited onto the package substrate strip. The first shielding material 206 is a partial shielding layer that does not extend over an entirety of the package substrate strip. As can be seen in FIG. 2C which shows a top view of the package substrate strip 201 after the deposition of the first shielding material 206, the first shielding material 206 covers entirely a side surface 202a of the encapsulant layer 202 facing towards the second electronic components 205. The first shielding material 206 further extends over a portion of the package substrate strip 201 adjacent to the side surfaces 202a of the encapsulant layer 202. The first shielding material 206 may also cover a portion of a top surface 202b of the encapsulant layer 202 adjacent to the side surfaces 202a of the encapsulant layer 202. In some examples, the first shielding material 206 may be formed by depositing a conductive material such as Al, Cu, Sn, Ni, Au, Ag, or any other suitable material for electromagnetic interference (EMI) shielding, onto the package substrate strip 201, in particular by spray coating. The first and second electronic components are for example situated on opposite sides of the first shielding material 206. In some examples, the conductive material may be Ag (silver) ink, which can be sprayed under the following condition shown in Table 1 below. Table 2 provides the properties of a coating material to be sprayed onto the substrate. However, it can be appreciated that various changes may be made to the condition for the spray process, and various other materials may be used.

TABLE 1
Spray Coating Condition (Package Strip Level)

| Nozzle speed | 5 to 30 | mm/sec |
|---|---|---|
| Coating pitch | 0.02 to 0.5 | mm |
| Nozzle diameter | 50 to 500 | um |
| Line width | 20 um to 1 mm | |
| Coating thickness | 3 to 20 | um |

| | |
|---|---|
| Nozzle angle | 90 deg relative to the |
| | surface of the substrate |

TABLE 2
Properties of Coating Material (NES-MA60 Series)

| Application | Aerosol spray |
|---|---|
| Solid contents (%) | 60 ± 2 |
| Filler contents (%) | 56 ± 2 |
| Curing Condition | 200° C. × 2 hr |

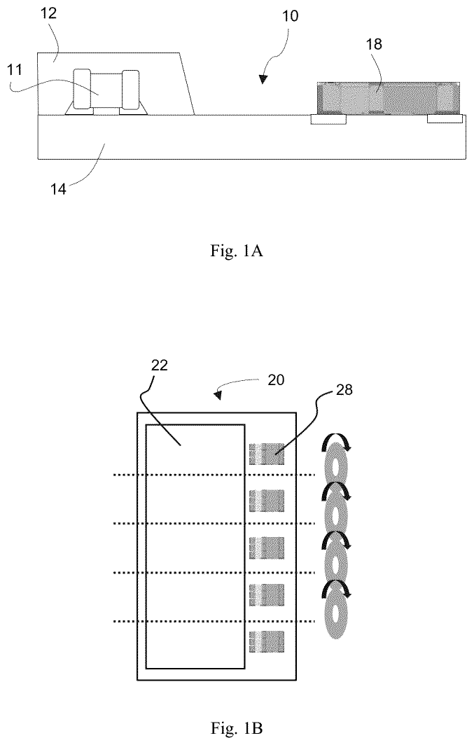

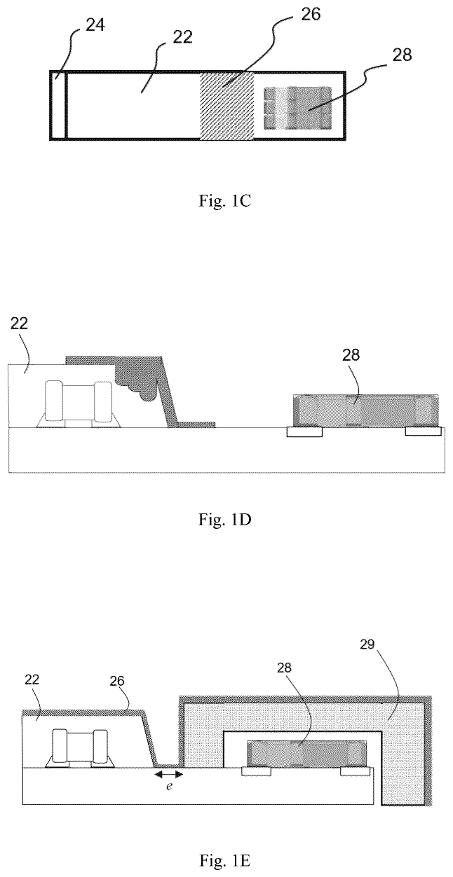

As can be seen in FIGS. 2B and 2C, since the package substrate strip 201 is not singulated into pieces at this stage, the first shielding material 206 may not flow down the side surfaces of the encapsulant layer 202 for each individual semiconductor device as described with reference to FIG. 1D. In addition, by applying the first shielding material 206 on the semiconductor substrate strip 201 before the singulating process, a high unit per hour (UPH) can be obtained because multiple packages can be processed simultaneously.

In a next step as illustrated in FIG. 2D, the package substrate strip 201 can be singulated, for example by cutting or laser ablation, into individual semiconductor packages or devices 210. In some embodiments, each of the semiconductor devices 210 may be in the form of a system-in-package (SiP) module in which various electronic components of a circuit system can be integrated within the semiconductor device 210 and mounted on a substrate 204 of the semiconductor device 210.

Next, as illustrated in FIG. 2E to FIG. 2G, a second shielding material may be further deposited on each individual semiconductor device 210, for example, using a cap-based sputtering method. The second shielding material may cover at least a portion of the first shielding material and some other surface of the encapsulant layer 202 which is free of the first shielding material. The combination of the first shielding material and the second shielding material forms a shielding layer for EMI shielding for the semiconductor device 210. In some embodiments, the second shielding material may be a SUS/Cu/SUS layer, wherein SUS refers to steel use stainless.

In particular, as illustrated in FIG. 2E, a deposition mask, for example in the form of a cap 209, is placed on the individual semiconductor device 210, to cover the second electronic components 205 but expose the encapsulant layer 202 or at least expose a portion of the encapsulant layer 202. The cap 209 may overlap at least partially with the first shielding material 206. For example, the cap 209 may overlap with a portion 206a of the first shielding material 206 that extends over the substrate 204. In some embodiments, a single deposition mask can be used to cover all the second electronic components 205. In a variant, a plurality of deposition masks can be used to cover respective second electronic components 205.

Next, as illustrated in FIG. 2F, a lower end of the cap 209 rests at least partially on the portion 206a of the first shielding material 206 that extends over the substrate 204. A second shielding material 207 may then be deposited onto the semiconductor device 210. The second shielding material 207 may be deposited continuously from the encapsulant layer 202 to the cap 209. The second shielding material 207 preferably covers at least regions of the top surface 202b and of the side surfaces 202a of the encapsulant layer 202 uncovered by the first shielding material 206. The second shielding material 207 may overlap at least partially with the first shielding material 206, for example, on the top surface 202b of the encapsulant layer 202. The second shielding material 207 may be formed by depositing a conductive material such as Al, Cu, Sn, Ni, Au, Ag, or any other suitable material for EMI shielding, onto the substrate, in particular by a sputtering process. In a variant, other similar chemical or physical vapor deposition process can be used to form the second shielding material 207. In some embodiments, the first and the second shielding materials can be formed of the same conductive material. In a variant, the first and the second shielding material can be formed of different conductive materials. As such, the entire shielding layer over the side surface 202a of the encapsulant layer 202 can be enhanced, since both the first and the second shielding materials can be deposited over the side surface 202a.

Afterwards, as illustrated in FIG. 2G, the cap can be removed from the semiconductor device 210. After removal of the cap 209, the encapsulant layer 202 is completely covered by the conductive shielding layer including the first and the second shielding materials 206 and 207, while the second electronic component 205 is left unshielded. In some embodiments, the second shielding material 207 may cover some of side surfaces of the substrate of the semiconductor device 210, such that the internal circuitry of the semiconductor device 210 can be electrically coupled to the shielding layer and thus grounded by the shielding layer.

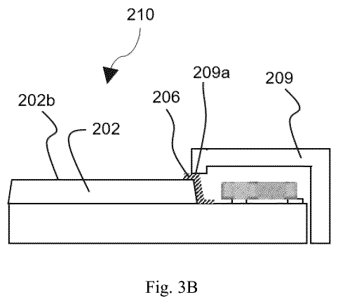

Some modifications can be made to the sputtering process as illustrated in FIGS. 2E to 2G. For example, in a variant illustrated in FIG. 3A, the lower end 209a of the cap 209 may rest against the side surface 202a of the encapsulant layer 202 facing towards the second electronic components 205. In another variant as illustrated in FIG. 3B, the lower end 209a of the cap 209 may rest on the top surface 202b of the encapsulant layer 202 with the first shielding material 206. Still, the first shielding material 206 and the second shielding material 207 have some overlapping portion that ensures desired shielding performance to the first electronic components encapsulated within the encapsulant layer 202.

The embodiment with respect to FIGS. 2A to 2G is started from a package substrate strip which has not been singulated. In some other embodiments, the method can be applied to a semiconductor package directly, for example, after it is singulated from a package substrate strip. In that case, a first shielding material may be deposited onto the package substrate of the semiconductor package. For example, the first shielding material is a partial shielding layer that does not extend over an entirety of the package substrate, but primarily covers entirely a side surface of an encapsulant layer of the semiconductor package facing towards second electronic components not covered by the encapsulant layer. In some embodiments, the first shielding material may cover a portion of a top surface of the encapsulant layer, and a portion of a top surface of the package substrate between the encapsulant layer and the second electronic components, which may be similar as the example shown in FIG. 2B. Afterwards, a second shielding material may be further deposited on the semiconductor package, for example, using a cap-based sputtering method. The second shielding material may cover at least a portion of the first shielding material and some other surface of the encapsulant layer which is free of the first shielding material. As such, the combination of the first shielding material and the second shielding material forms a shielding layer for EMI shielding for the semiconductor package. Furthermore, in some alternative embodiments, the second shielding material may be deposited using the cap-based sputtering method, prior to the deposition of the first shielding material using the spray coating method. In that case, even if there may be some first shielding material flowing down a side surface of the encapsulant layer, there is still sufficient shielding material over the top surface of the encapsulant layer because the second shielding layer is also deposited there.

In the embodiments of the present invention, since the side surface of the encapsulant layer facing towards the second electronic components is already covered by the first shielding material deposited by a spray coating process, there is no need to form a second layer of shielding material over the side surface of the encapsulant layer during the subsequent sputtering process. Therefore, during the deposition of the second shielding material by the sputtering process, a gap between the deposition mask and the encapsulant layer is not desired. Therefore, the distance between shielded electronic components and eventually other unshielded electronic components, for example a board-to-board (B2B) connector in a B2B area, may be reduced significantly. In this way, the number of components in the area can be increased or the component size benefits are obtained, which allows to improve the form factor of the semiconductor device. Therefore, it is possible to apply small form factor during package design or to mount more components or consider larger-sized components and thus improve package design.

Certain measurements such as shielding resistance measurement have been conducted to the partially shielded semiconductor devices made using the method according to some embodiments of the present application. Compared with the devices made using conventional sputtering method, a difference between the resistance measurements to the shielding layers of these two types of devices is only smaller than 10%, which is generally acceptable. However, as mentioned above, the method according to some embodiments of the present application has the benefit of an increased level of integration and reduced occupation of package substrates.

The discussion herein included numerous illustrative figures that showed various portions of a semiconductor device with a partial shielding layer and a method for making such semiconductor device. For illustrative clarity, such figures did not show all aspects of each example assembly. Any of the example assemblies and/or methods provided herein may share any or all characteristics with any or all other assemblies and/or methods provided herein.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A method for making a semiconductor device, comprising:
providing a package substrate strip mounted thereon multiple sets of first electronic components and multiple sets of second electronic components;
forming an encapsulant layer on the package substrate strip that covers the multiple sets of first electronic components;
forming a first shielding material by spray coating such that the first shielding material extends continuously from a top surface of the encapsulant layer to a top surface of the package substrate strip to cover at least a side surface of the encapsulant layer facing towards the multiple sets of second electronic components;
singulating the package substrate strip into individual semiconductor packages with respective package substrates; and
forming a second shielding material on the encapsulant layer by sputtering, wherein the second shielding material at least partially overlaps with the first shielding material.

2. The method of claim 1, wherein the step of forming a second shielding material comprising:
placing a deposition mask to cover the second electronic components, the deposition mask overlapping at least partially with the first shielding material;
depositing the second shielding material to the semiconductor package by sputtering; and
removing the deposition mask from the semiconductor package.

3. The method of claim 2, wherein the deposition mask overlaps with the first shielding material on a portion of the first shielding material extending over the package substrate.

4. The method of claim 2, wherein the second shielding material covers entirely the top surface and side surfaces of the encapsulant layer.

5. The method of claim 1, wherein the step of forming an encapsulant layer comprises forming the encapsulant layer using an injection molding process.

6. The method of claim 5, wherein the encapsulant layer has a shape of a truncated prism with sloping sidewalls at its periphery.

7. A semiconductor device which is formed using the method of claim 3.

8. A semiconductor device which is formed using the method of claim 4.

9. A semiconductor device which is formed using the method of claim 6.

10. A method for making a semiconductor device, comprising:
providing a package substrate mounted thereon first electronic components and second electronic components;
forming an encapsulant layer on the package substrate that covers the first electronic components;
forming a first shielding material by spray coating such that the first shielding material extends continuously from a top surface of the encapsulant layer to a top surface of the package substrate strip to cover at least a side surface of the encapsulant layer facing towards the second electronic components; and
forming a second shielding material on the encapsulant layer by sputtering, wherein the second shielding material at least partially overlaps with the first shielding material.

11. The method of claim 10, wherein the step of forming a second shielding material comprising:
placing a deposition mask to cover the second electronic components, the deposition mask overlapping at least partially with the first shielding material;
depositing the second shielding material to the package substrate by sputtering; and
removing the deposition mask from the package substrate.

12. The method of claim 11, wherein the deposition mask overlaps with the first shielding material on a portion of the first shielding material extending over the package substrate.

13. The method of claim 11, wherein the second shielding material covers entirely the top surface and side surfaces of the encapsulant layer.

14. The method of claim 10, wherein the step of forming an encapsulant layer comprises forming the encapsulant layer using an injection molding process.

15. The method of claim 14, wherein the encapsulant layer has a shape of a truncated prism with sloping sidewalls at its periphery.
